(19) United States
(12) Patent Application Publication
(10) Pub. No.: US 2018/0102762 A1
(43) Pub. Date: Apr. 12, 2018

(54) LINEAR PHASE RESONATOR FILTERS

(71) Applicant: Leland Peter Solie, Chetek, WI (US)

(72) Inventor: Leland Peter Solie, Chetek, WI (US)

(21) Appl. No.: 15/286,902

(22) Filed: Oct. 6, 2016

(51) Int. Cl. H03H 9/54; H03H 9/64

(52) U.S. Cl. CPC H03H 9/6406; H03H 9/54; H03H 7/01

(57) ABSTRACT

The present invention provides a means of electrically connecting a number of resonant filters together to produce a bandpass filter with the following properties: a relative bandwidth that can be several times wider than a single resonant circuit of the same type, a linear phase frequency response across the passband (which is normally not the case for resonator filters), lower loss and smaller size than can be achieved with transversal filters (but are typical of resonator filter). The invention describes the design constraints on the resonant filters that make these results possible.

### CROSS REFERENCE TO RELATED APPLICATION

This application claims the benefit of U.S. provisional application No. 62/389,727 filed on Mar. 8, 2016, incorporated by reference herein.

### FIELD OF THE INVENTION

The present invention relates generally to bandpass filters using acoustic wave technology including surface acoustic waves (SAW), bulk acoustic waves (BAW), surface skimming bulk waves (SSBAW), pseudosurface waves (PSAW), and other wave modes, solidly mounted resonators (SMR) and film bulk acoustic resonators (FBAR). More specifically it relates to techniques for implementing a bandpass filter using resonant elements, including acoustic wave resonant elements, or lumped element circuitry including lumped element resonator circuits and ladder filters. Bandpass filters are widely used in telecommunication and data transmission systems and other high frequency applications.

### BACKGROUND AND BRIEF DESCRIPTION OF THE RELATED ART

Prior to 1970 most bandpass filters were implemented using lumped elements, such as resistors, capacitors, and inductors, as in IF filters in heterodyne receivers and receiver front end RF filters. In the 1960's and 1970's SAW transversal filters were introduced for use as TV IF filters and for use in a wide range of military radar and communication systems. Commercial use soon followed wherever compact bandpass filters were needed. In the 1970's SAW resonator filters were introduced primarily for narrowband applications. Since resonator circuits can be implemented using a variety of techniques such as SAW, BAW, SSBAW, PSAW, FBAR, and lumped elements, for convenience the full list of techniques will not be continually repeated throughout this discussion, but the full list will be assumed whenever SAW resonator technology is being discussed.

Nearly all SAW bandpass filters fall into one of two categories, i.e., transversal filters or resonator based filters. Each type has its unique advantages and disadvantages. The filter design techniques for the two types of filters are totally different. Resonator filter designs involve the placement of poles and zeros in the frequency domain, whereas transversal filters are implemented in the time domain, and the resulting frequency domain response is derived by taking the Fourier transform of the time response.

The advantages of transversal filters can be listed as follows: 1) More flexibility in the design of the frequency response. The time response can be controlled at every tap of a transversal filter so a great deal of design control is possible. In principle, an arbitrary band limited frequency response (the target response) can be chosen. The inverse Fourier Transform (IFT) of this defines a time domain response. This time domain response can be implemented with the taps of a transversal filter. The resulting frequency response of this filter will approximate the target frequency response. A useful consequence of this design approach is that one can use as a target response a bandpass filter with a high shape factor (near rectangular in shape), one with a flat passband, steep skirts, and high out of band rejection. This rectangular passband shape is a desirable property for most passband filters, and transversal filters are superior to resonator filters in their ability to approximate this ideal response. 2) Transversal bandpass filters can easily be designed to have a linear phase response, i.e., the phase response of the filter will be linear if the time response is symmetrical, and this is generally possible.

The advantages of resonator filters are as follows: 1) they are generally smaller in size. Smaller size, in itself, is desirable where ever space is at a premium, such as in a cell phone, but also smaller size results in lower cost. 2) Resonator filters are generally lower loss than their transversal filter counterparts. Lower loss reduces the need for additional amplification to make up for the loss, and loss generally reduces the signal to noise ratio of the system which can be very important. 3) Transversal filters can have relative fractional bandwidths considerably wider that resonator filters.

### SUMMARY OF THE INVENTION

The present invention relates to a means of electrically connecting a number of resonator filters together and to the design of these resonator filters in a manner which creates a new class of filters that have the advantages of both transversal and resonator filters. This new class of filters has the lower loss and smaller size characteristics of resonator filters and potentially a rectangular passband response, linear phase response, and a wider relative bandwidth typical of transversal filters (not fully as wide but much wider than resonator filters). This new class of filters, which is the subject of this invention, will be called a Linear Phase Resonator Filter.

### DETAILED DESCRIPTION OF THE PREFERRED EMBODIMENTS

The essence of the present invention is that it is possible to create a new class of filters by connecting a number of conventional resonator filters electrically in parallel, and the resulting filter will have performance capabilities that have previously not been possible with either resonator filters alone or transversal filters alone. Clearly the design parameters of these conventional resonator filters are critical to the operation of this new class of filters, and so the focus of this section will be how these conventional resonator filters can be designed individually and in relationship with one another to create a total filter with performance characteristics that are not possible with any single conventional resonator filter. It is necessary at this point to define a few terms.

A “basic resonator filter” or BRF is defined as a conventional resonator filter using any resonator structure that is known in the present state of the art. It may be based on any of the previously mentioned propagating wave technologies such as SAW, PSAW, BAW, SSBAW, FBAR, or any other acoustic wave mode or structure known to the state of the art. In addition it can include resonator ladder filters and lumped element resonant filters. Secondly, the BRF is understood to be a two-port device, with an input port (with 2 terminals) and an output port (with 2 terminals). Third, the BRF is assumed to be a passband filter with a center frequency F_{c} and a 6 dB bandwidth BW_{6 dB}. Since the center frequencies F_{c} are different for each BRF the ith center frequency can be designated F_{ci}. As an example a BRF could be an in-line 2-port resonator filter beginning with a first (SAW) reflector followed by a first transducer (input), followed by a second reflector, followed by a second transducer (output) followed by a third reflector all in a single acoustic track. The acoustic gaps between these elements (reflectors and transducers), the periodicities of the reflectors and transducers, and the number of electrodes in these elements are important but are part of the state of the art, and so there is no need to discuss them here. When properly designed it is a simple bandpass filter with a center frequency F_{c} and a 6 dB bandwidth BW_{6 dB}. This is a BRF, but for reasons which will be discussed later, it may not satisfy all of the requirements for use in this invention (to be discussed later). There are several other BRF structures using two or more reflectors between the input and output transducers and also structures using two or more acoustic tracks where the acoustic energy is transferred (coupled) to an adjacent track by means of transducers or multistrip couplers or evanescent coupling due to the proximity of the tracks. Any of these resonator filters may be a potential candidate as a BRF for this invention.

According to the present invention, a “linear phase composite resonator filter” or LPCRF is made by connecting several of these BRF's electrically in parallel. Since each BRF is a 2-port device with 2 terminals at each port, the input ports of all the BRFs are connected in parallel, and the output ports of the BRFs are likewise all connected in parallel. The manner in which they are connected to the input or output bus bars matters, because if the terminals at either port are switched the polarity of the response is switched by 180°. It is assumed, unless explicitly stated otherwise, that the terminals of all the BRFs are connected to the major (input or output) bus bars in the same manner (polarity). The BRFs are not identical to one another, but have different center frequencies F_{ci}. The center frequencies are stepped by an amount of approximately BW_{6 dB}. In this case the frequency responses of the BRFs cross at approximately their 6 dB points. The fact that the center frequencies of the BRFs are stepped is an essential or defining difference between a LPCRF, which is the subject of this invention, and other BRFs which are part of the state of the art. Any BRF involving waves propagating near or at the surface of a substrate (SAW, SSBAW, PSAW) require distributed reflectors or reflecting strips to establish resonant cavities. The periodicity of a distributed reflector is defined by its stopband frequency. In a BRF the stopband frequencies of all the reflectors within a single BRF are similar in value. They fall within a range of values not much larger than the bandwidth of the filter, i.e., BW_{6 dB}. Widening of the bandwidth of a filter is achieved by mode splitting between the modes of the resonant cavities within a single BRF, and the magnitude of this widening is quite limited. In the case of this invention the widening of the overall bandwidth of the LPCRF is achieved by using several BRFs which are stepped in frequency where the steps are such that in the frequency domain the responses of adjacent channels cross at their 6 dB points. This widening can be quite significant, and in fact is proportional to the number of BRFs within the LPCRF. If there are N BRFs used in a LPCRF, the total bandwidth of the LPCRF will be about N times larger than the bandwidth of a single BRF. Since the BRFs are all connected in parallel the responses add resulting, hopefully, in a flat bandpass response for the LPCRF. That is the essence of this invention, but it is not quite so straight forward. There are two potential issues that could degrade the LPCRF response.

The first is that, in order for the LPCRF response to have a flat passband, the phase of any two BRFs in the LPCRF at their crossover points must be such that they add (constructively) and do not subtract or cancel one another. In the case of a LPCRF comprised of the example BRFs in paragraph [0009] the BRF responses would indeed cancel at their crossover points because the phase shift across the 6 dB passband is approximately 180°. In this case the overall response of the LPCRF would be a series of lobes separated by deep nulls rather than a smooth, flat overall passband. This places a condition on the BRFs which is that the phases of the signals from the two channels or BRFs that cross at their 6 dB crossings must be such that they add constructively. It is reasonable to assume that the general layout (not the exact parameters) of the BRFs in a single LPCRF are the same. It is possible and part of the state of the art to change the phase shift (by adding poles and/or zeros to the resonator, or by switching terminals from the BRF to the input or output bus bars, or by adding additional reflectors in the acoustic path, etc.) so that they add constructively at these crossover points. As an example consider a BRF which is a SAW resonator consisting of a first reflector, followed by a first transducer, followed by a second reflector and a third reflector, followed by a second transducer, followed by a fourth reflector all in a single acoustic path. In this example the phase shift across the 6 dB band width is 360° and the transmission phase at the two 6 dB points are +/−180°. Since at the crossover point a signal with a phase of +180° adds constructively with a signal at −180° the response of the LPCRF at this and all other crossovers will be smooth and flat. Since this is part of the state of the art it is not necessary to discus it further here than to say that the phases of the signals at their 6 dB crossover points must be such that they add in phase (constructively). This is the first issue.

The second issue that can degrade the response of a CRF is the fact that when the BRFs are connected in parallel they are highly interactive. Each BRF sees all the other BRFs to which it is connected as parts of an electrical matching circuit, and the individual BRF responses can be altered considerably. The only solution to this problem is to use a good modeling program and an optimization routine to perturb the design parameters of the BRFs to achieve an optimally flat passband with optimal out of band rejection. This process is familiar to SAW designers in structures like R-SPUDT (Reflective Single Phase UniDirectional Transducer) filters where modeling and optimization are used to design a filter. Since this optimization procedure is well known to those familiar with the state of the art, it is not a part of this invention.

What is claimed is:

1. A structure consisting of a filter input port and a filter output port and a number, greater than one, of 2-port basic resonator filters, where all the input ports of said basic resonator filters are connected in parallel to said filter input port and the output ports of said basic resonator filters are connected in parallel to said filter output port.

2. A structure as described in claim #1 where said basic resonator filters are stepped in frequency from a lowest center frequency to a highest center frequency in sequential order.

3. A structure as described in claim #2 where adjacent said basic resonator filters in said sequential order have crossover points in the frequency domain which are approximately 6 dB below the peak of each passband response. The crossover points within a single said basic resonator filter define the 6 dB bandwidth.

4. A structure as described in claim #3 where the transmission phase response at said 6 dB crossover points of the signals from the two said basic resonator filters are such that they add constructively.

5. A structure as described in claim #4 where each said basic resonator filter is a 2-port SAW resonator filter.

6. A structure as described in claim #4 where each said basic resonator filter is a 2-port pseudo SAW (PSAW) resonator filter.

7. A structure as described in claim #4 where each said basic resonator filter is a 2-port surface skimming bulk wave (SSBAW) resonator filter.

8. A structure as described in claim #4 where each said basic resonator filter is a 2-port bulk acoustic wave (BAW) resonator filter.

9. A structure as described in claim #4 where each said basic resonator filter is a 2-port FBAR resonator filter.

10. A structure as described in claim #4 where each said basic resonator filter is a 2-port lumped element resonator filter.

11. A structure as described in claim #4 where each said basic resonator filter is a ladder resonator filter.

12. A structure as described in claim #4 where each said basic resonator filter is any 2-port electronic or electrical resonator filter.
